(19) United States
(12) Patent Application Publication
(10) Pub. No.: US 2008/0087889 A1
(43) Pub. Date: Apr. 17, 2008

(54) Method of fabricating an organic electroluminescent device and system of displaying images

(75) Inventors: Chuan-Yi Chan, Taipei City (TW); Chun-Yen Liu, Jhubei City (TW); Chang-Ho Tseng, Sinwu Township (TW)

Correspondence Address: LIU & LIU, 444 S. FLOWER STREET, SUITE 1750, LOS ANGELES, CA, 90071, US

(73) Assignee: TPO Displays Corp.

(21) Appl. No.: 11/975,038

(22) Filed: Oct. 16, 2007

(30) Foreign Application Priority Data
Oct. 16, 2006 (TW) 095138022

(51) Int. Cl. H01L 51/50; H01L 21/336

(52) U.S. Cl. 257/40; 438/29; 257/E21.412; 257/E51.018

(57) ABSTRACT

A method for fabricating organic electroluminescent devices is disclosed. The method comprises providing a substrate divided into first and second regions, forming an amorphous silicon layer on the substrate, forming a protection film on the amorphous silicon layer within the second region, performing an excimer laser annealing process on the amorphous silicon layer for converting it to a polysilicon layer, removing the protection film, patterning the polysilicon layer, thus a first patterned polysilicon layer in the first region and a second patterned polysilicon layer in the second region are formed. A resultant organic electroluminescent device is obtained. Specifically, the grain size of the first patterned polysilicon layer is large than that of the second patterned polysilicon layer.

### BACKGROUND OF THE INVENTION

1. Field of the Invention

The present invention relates to a method for fabricating an electroluminescent device, and in particular relates to a method for fabricating a thin film transistor (TFT).

2. Description of the Related Art

A conventional thin film transistor (TFT), can be an amorphous silicon TFT or a polysilicon silicon TFT, includes light emitting and circuit regions. A fabrication method thereof mainly includes the steps of forming TFTs, forming a pixel electrode and forming organic light emitting diodes. Fabrication processes of a TFT typically include forming buffer layer, polysilicon layer, gate insulating layer, gate electrode and interlayer dielectric overlying the overall substrate surface in sequence. A pixel electrode electrically connected to the TFTs is then formed after the completion of the TFTs. Thereafter, a resultant electroluminescent device is obtained by sequential formation of transparent electrode, organic light emitting layer and reflection cathode overlying the light emitting region. In a fabrication method of polysilicon TFTs, an exicimer laser annealing process is usually utilized to transform the amorphous silicon layer overlying the buffer layer to a polysilicon layer, thus a polysilicon TFT is obtained.

The polysilicon TFTs (for example, serving as a driving TFT) produced by the exicimer laser annealing process, however, have various mobility, leading to a problem such as non-uniform luminance between pixels that render a defect so called mura.

Accordingly, an electroluminescent device capable of solving the described issues is desirable.

### BRIEF SUMMARY OF THE INVENTION

In view of the problems in conventional processes, the addition of the protection film is proposed to decrease the difference of electric properties between TFTs. Furthermore, the aperture can be increased, even in a shorter channel length, by the addition of the protection film.

An embodiment of a method for fabricating organic electroluminescent devices is disclosed. The method comprises providing a substrate divided into first and second regions, forming an amorphous silicon layer on the substrate, forming a protection film on the amorphous silicon layer within the second region, performing an excimer laser annealing process on the amorphous silicon layer for converting it to a polysilicon layer, removing the protection film, patterning the polysilicon layer, thus a first patterned polysilicon layer in the first region and a second patterned polysilicon layer in the second region are formed. A resultant organic electroluminescent device is obtained. Specifically, the grain size of the first patterned polysilicon layer is large than that of the second patterned polysilicon layer.

Another embodiment of a method for fabricating an organic electroluminescent devices, comprising: providing a substrate comprising a pixel area including a plurality of pixels, wherein each pixel is divided into first and second regions; forming a patterned protection film overlying the second region; forming a amorphous silicon layer overlying the substrate and patterned protection film; performing an excimer laser annealing process on the amorphous silicon layer for converting it to a polysilicon layer; and patterning the polysilicon layer, thus a first patterned polysilicon layer in the first region and a second patterned polysilicon layer in the second region are formed, wherein the grain size of the first patterned polysilicon layer is large than that of the second patterned polysilicon layer.

Another embodiment of a system for displaying images comprises an organic electroluminescent device. The organic electroluminescent comprises a substrate with a pixel area thereon, wherein the pixel area comprises a plurality of pixels, each pixel comprises a switching region and a driving region; a switching TFT in the switching region; and a driving TFT in the driving region, at least comprising a gate electrode, a polysilicon layer underlying the gate electrode and a patterned protection film underlying the polysilicon layer, wherein the patterned protection film that is a metal layer is between the polysilicon layer and the substrate.

By utilizing the embodiments of the invention, issues such as extreme difference of electric properties existing between TFTs, low aperture can be improved without an increase of process complexity.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is an equivalent circuit of a sub-pixel of an organic electroluminescent device.

FIGS. 2a˜2f are cross sections showing an embodiment of a method for fabricating an organic electroluminescent device.

FIGS. 3a˜3f are cross-sections showing an embodiment of a method for fabricating an organic electroluminescent device.

FIGS. 4a˜4g are cross sections showing an embodiment of a method for fabricating an organic electroluminescent device.

FIGS. 5a˜5g are cross sections showing an embodiment of a method for fabricating an organic electroluminescent device.

FIG. 6 schematically shows another embodiment of a system for displaying images.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

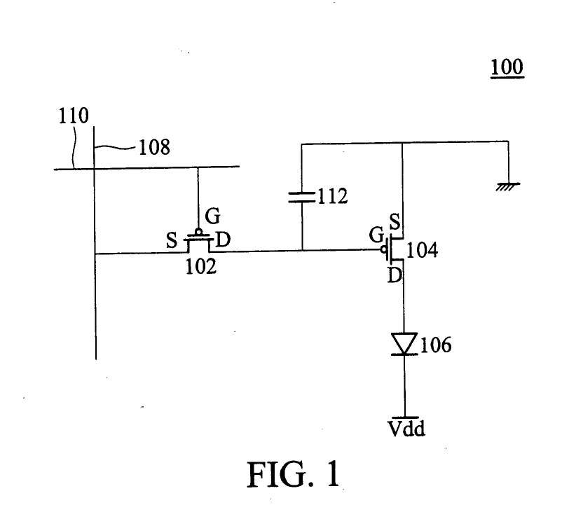

FIG. 1 is an equivalent circuit of a pixel of an organic electroluminescent device. It is noted that each “pixel” hereinafter includes a switching TFT and a driving TFT.

As shown in FIG. 1, in a pixel area (not shown) including a plurality of pixels, one pixel 100 comprises a switching TFT 102, a driving TFT 104, an organic light emitting diode 106, a data line 108, a scan line 110, and a storage capacitor 112. The organic light emitting diode 106 further comprises an anode electrode, an electroluminescent layer and a cathode electrode (not shown). Note also that the switching TFT 102 and driving TFT 104 are formed in a same pixel.

### First Embodiment

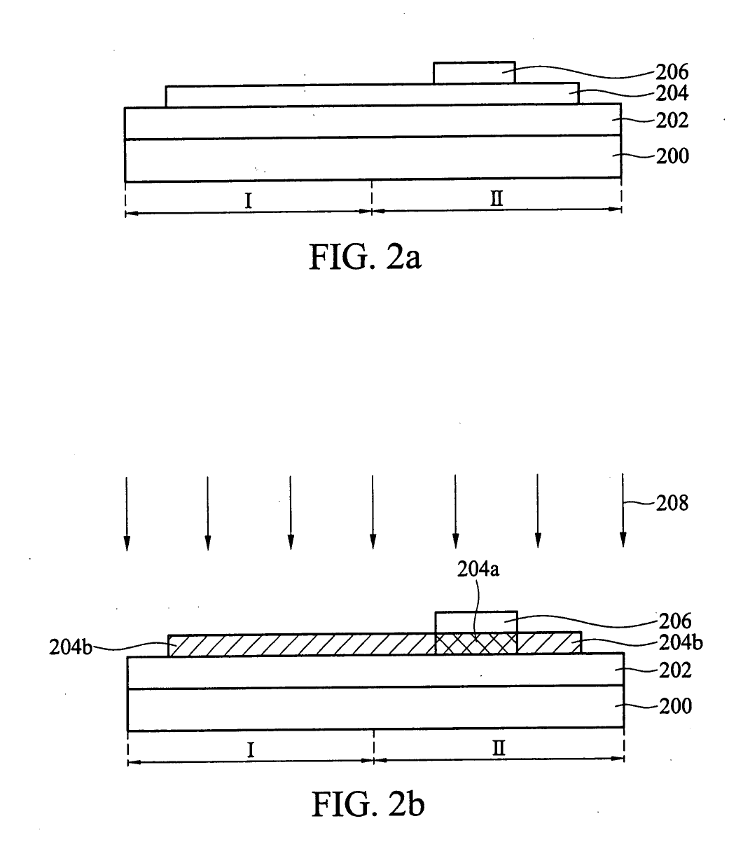

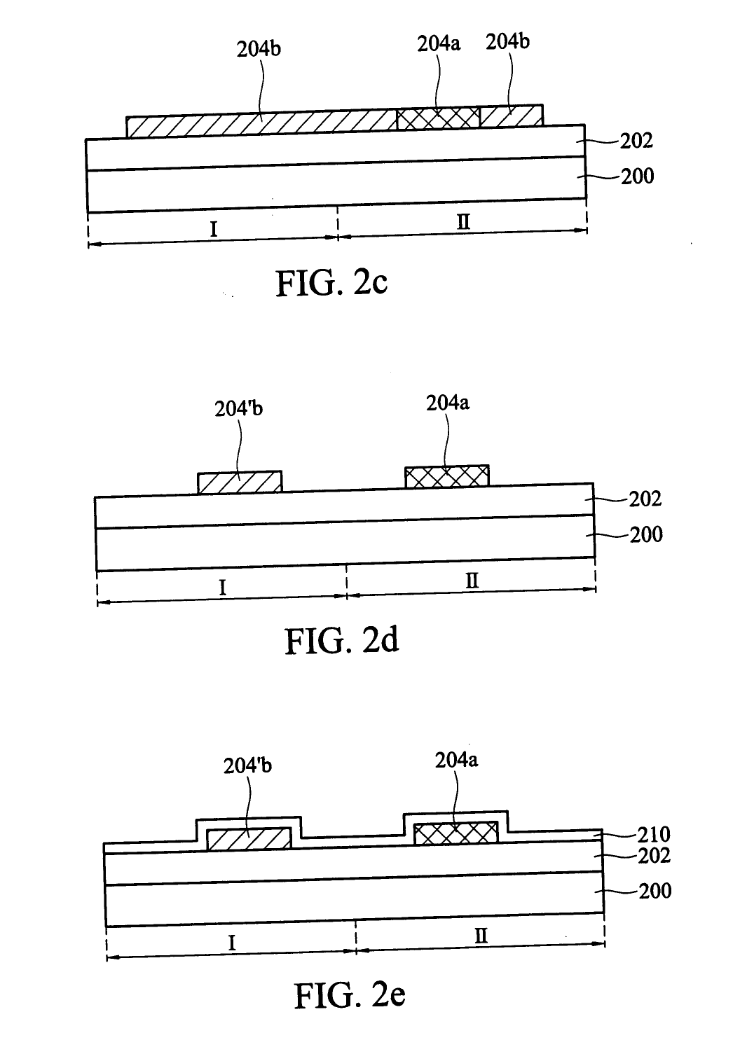

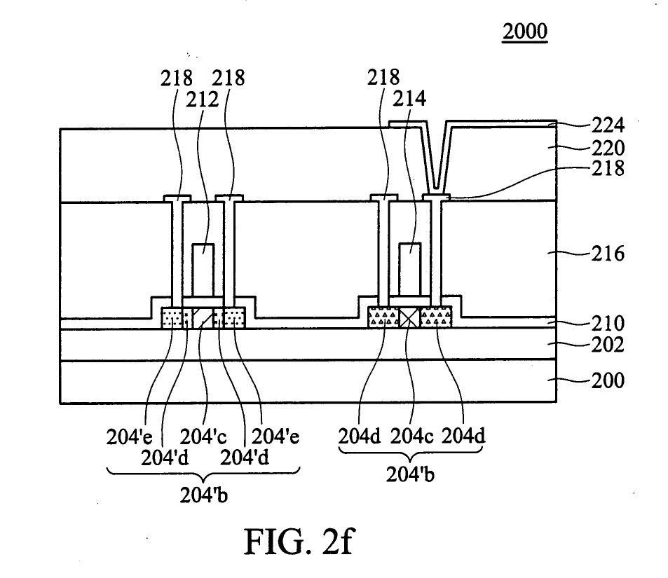

FIGS. 2a˜2f are cross sections showing an embodiment of a method for fabricating an organic electroluminescent device.

As shown in FIG. 2a, a buffer layer 202, an amorphous silicon layer 204 and a protection film 206 are formed sequentially overlying a substrate 200 divided into a first region (for example, a switching TFT region I) and a second region (for example, a driving TFT region II). The protection film 206 is formed on a portion of the amorphous silicon layer 204 in the second region II, and includes silicon-based materials such as SiOx, SiNx, SiOxNy or a stack of SiOx, SiNx.

As shown in FIG. 2b, the amorphous silicon layer 204 proceeds an excimer laser annealing (ELA) process 208 and transforms to polysilicon layers 204a and 204b. The polysilicon layers 204a and 204b, however, have different grain size because the protection film 206 can reflect a portion laser in the excimer laser annealing (ELA) process 208. That is, the polysilicon layer 204b uncovered by the protection film 206 possesses greater grain size due to its direct exposure to the excimer laser, and has a mobility of about 100 cm² V-s. The polysilicon layer 204a underlying the protection film 206, however, can get smaller and uniform grain size because the protection film 206 reflects a portion of laser. The polysilicon layer 204a has a mobility of about 100 cm² V-s.

As shown in FIG. 2c, the protection film 206 is removed. As shown in FIG. 2d, the polysilicon layers 204a and 204b are patterned to form a first active layer 204′b in the switching TFT region I and a second active layer 204a in the driving TFT region II.

As shown in FIG. 2e, a gate dielectric layer 210 is formed to cover the buffer layer 202, patterned polysilicon layers i.e. the first active layer 204′b, second active layer 204a.

As shown in FIG. 2f, subsequent processes proceeds in sequence, forming gate electrodes 212 and 214, interlayer dielectric 216, conductive line 218, cap layer 220 and transparent electrode (pixel electrode) 224. The subsequent processes are well known, thus are omitted here. As a result, an organic electroluminescent device 2000 with switching and driving TFTs is obtained. The switching TFT includes a gate electrode 212, a gate dielectric layer 210 and a first active layer 204′b and the driving TFT includes a gate electrode 214, a gate dielectric layer 210 and a second active layer 204a. The first active layer 204′b includes a channel region 204′c, lightly doped drains 204′d, source/drain electrodes 204′e and the second active layer 204a includes a channel region 204c and source/drain electrodes 204d.

### Second Embodiment

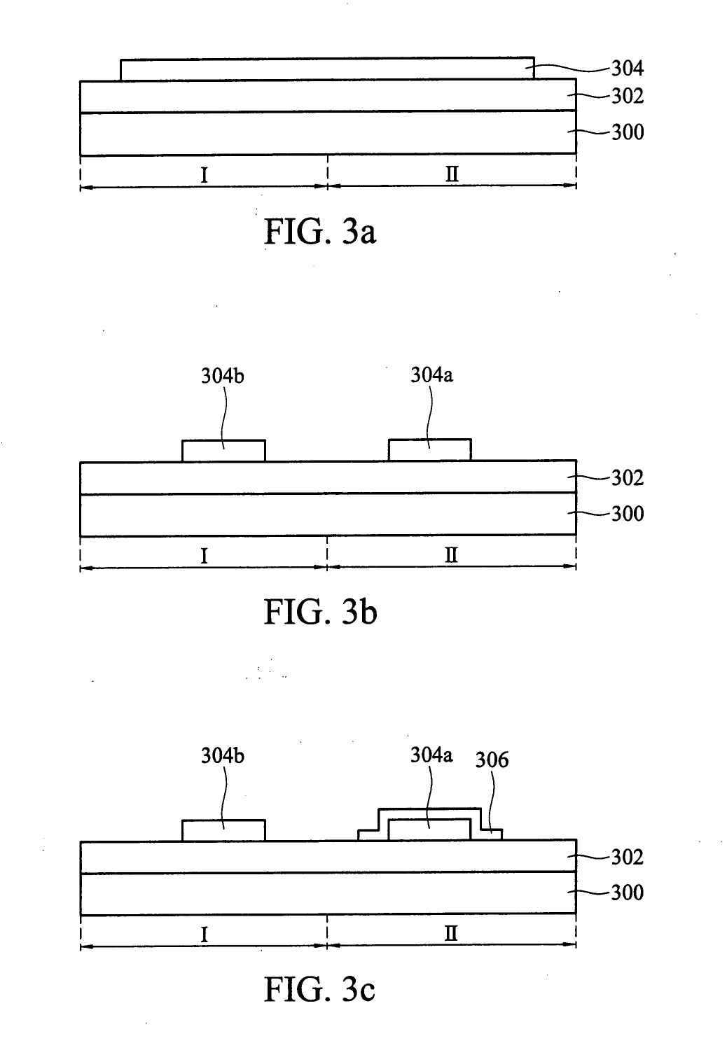

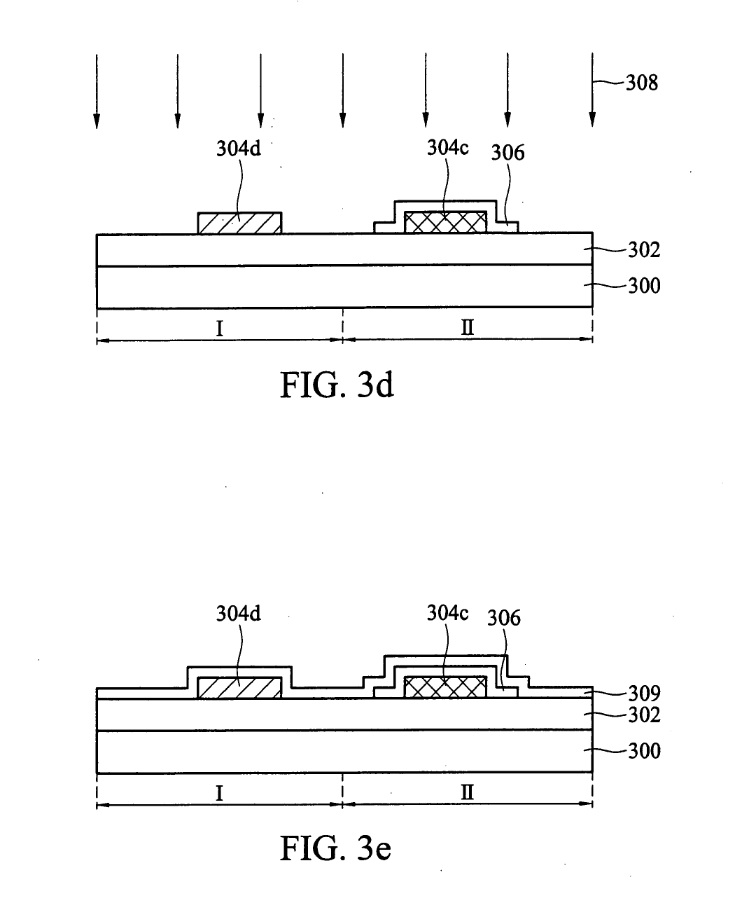

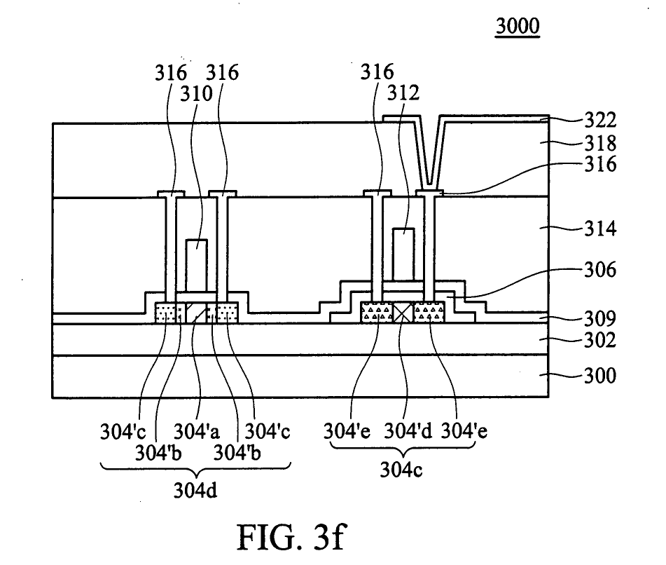

FIGS. 3a˜3f are cross-sections showing an embodiment of a method for fabricating an organic electroluminescent device.

As shown in FIG. 3a, a buffer layer 302 and amorphous silicon layer 304 are formed sequentially overlying a substrate 300 divided into a switching TFT region I and a driving TFT region II.

As shown in FIG. 3b, the amorphous silicon layer 304 is patterned, thus a patterned amorphous silicon layer 304b in the switching TFT region I and a patterned amorphous silicon layer 304a in the driving TFT region II are formed.

As shown in FIG. 3c, a protection film 306 is formed covering the patterned amorphous silicon layer 304a and a portion of the buffer layer 302, and includes silicon-based materials such as SiOx, SiNx, SiOxNy or a stack of SiOx, SiNx.

As shown in FIG. 3d, the patterned amorphous silicon layers 304a and 304b proceeds an excimer laser annealing (ELA) process 308 and transforms to polysilicon layers 304c and 304d. The polysilicon layers 304d in the switching TFT region I serves a first active layer of the switching TFT formed later and the polysilicon layer 304c in the driving TFT region II serves a second active layer of the driving TFT formed later. The polysilicon layers 304c and 304d, however, have different grain size because the protection film 306 can reflect apportion laser in the excimer laser annealing (ELA) process 308. That is, the polysilicon layer 304b uncovered by the protection film 306 possesses greater grain size due to its direct exposure to the excimer laser, and has a mobility of about 100 cm² V-s. The polysilicon layer 304c underlying the protection film 306, however, can get smaller and uniform grain size because the protection film 306 reflects a portion of laser. The polysilicon layer 304c has a mobility of about 100 cm²/V-s.

As shown in FIG. 3e, a gate dielectric layer 309 is formed to cover the buffer layer 302, patterned polysilicon layers i.e. the first active layer, second active layer.

As shown in FIG. 3f, subsequent processes proceeds in sequence, forming gate electrodes 310 and 312, interlayer dielectric 314, conductive line 316, cap layer 318 and transparent electrode (pixel electrode) 322. The subsequent processes are well known, thus are omitted here. As a result, an organic electroluminescent device 3000 with switching and driving TFTs is obtained. The switching TFT includes a gate electrode 310, a gate dielectric layer 309 and a first active layer; the driving TFT includes a gate electrode 312, a gate dielectric layer 309 and a second active layer. The first active layer includes a channel region 304′a, lightly doped drains 304′b, source/drain electrodes 304′c; the second active layer 304′d includes a channel region 304′d and source/drain electrodes 304′e.

### Third Embodiment

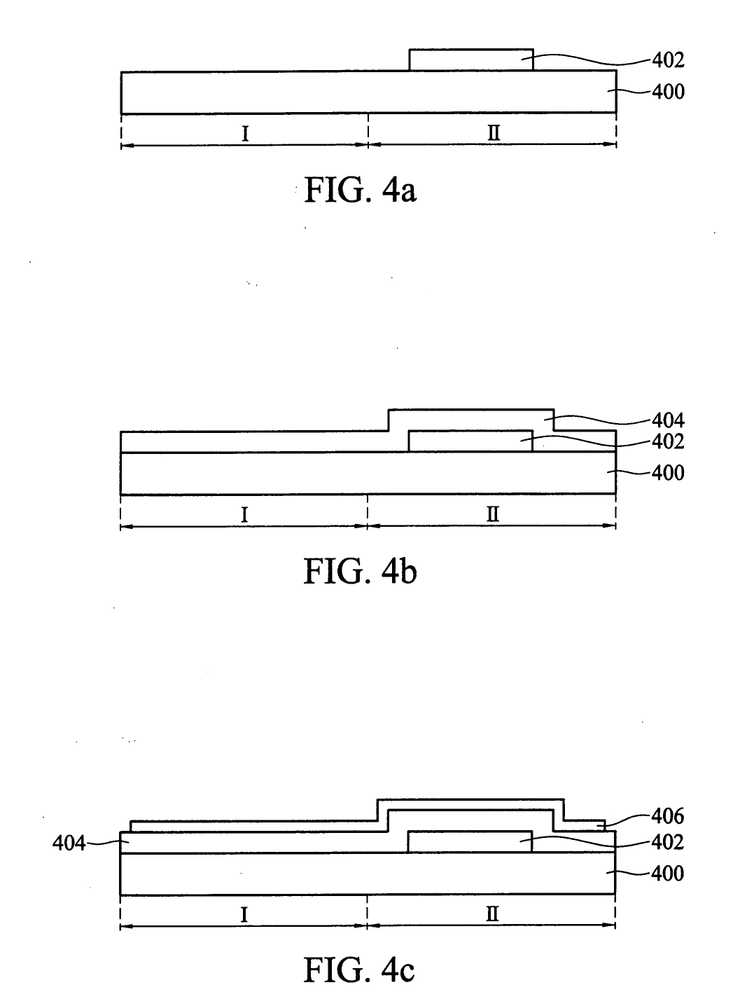

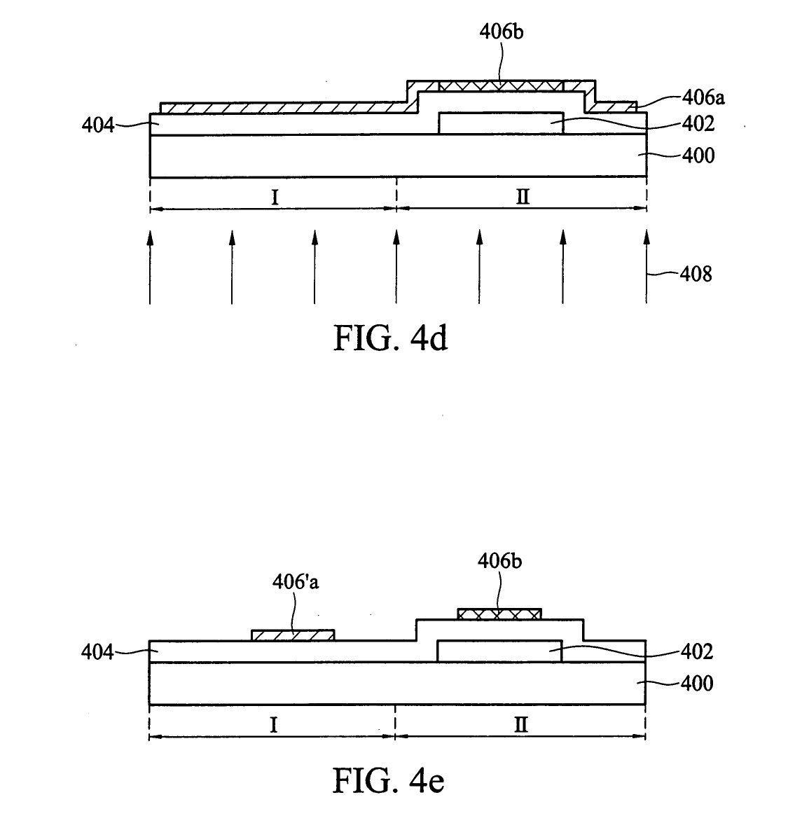

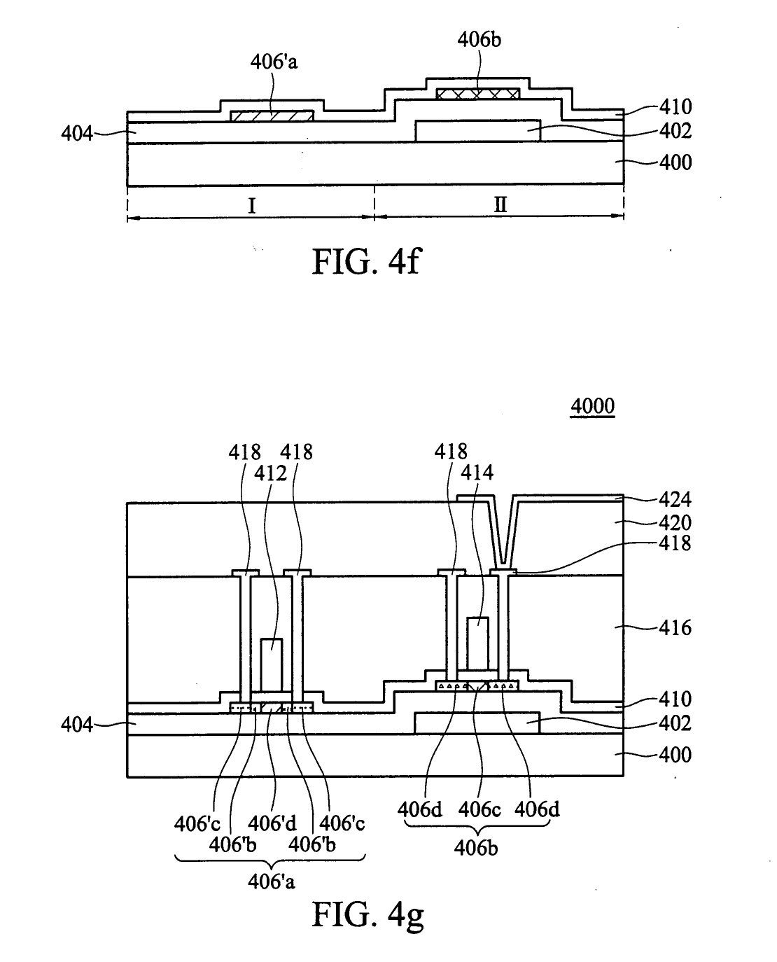

FIGS. 4a˜4g are cross sections showing an embodiment of a method for fabricating an organic electroluminescent device.

As shown in FIG. 4a, a protection film 402 is formed overlying a substrate 400 divided into a switching TFT region I and a driving TFT region II. The protection film 402 includes silicon-based materials such as SiOx, SiNx, SiOxNy or a stack of SiOx, SiNx.

As shown in FIG. 4b, a buffer layer 404 is formed overlying the patterned protection film 402 and the substrate 400. As shown in FIG. 4c, an amorphous silicon layer 406 is formed overlying the buffer layer 404.

As shown in FIG. 4d, the amorphous silicon layer 406 proceeds an excimer laser annealing (ELA) process 408 and transforms to polysilicon layers 406a and 406b.

As shown in FIG. 4e, patterned polysilicon layers 406′a and 406b are formed after a patterning process of the polysilicon layers 406a and 406b. The polysilicon layers 406′a in the switching TFT region I serves a first active layer of the switching TFT formed later and the polysilicon layer 406b in the driving TFT region II serves a second active layer of the driving TFT formed later. The polysilicon layers 406′a and 406b, however, have different grain size because the patterned protection film 402 can reflect apportion laser in the excimer laser annealing (ELA) process 408. That is, the patterned polysilicon layer 406′a possesses greater grain size due to its direct exposure to the excimer laser, and has a mobility of about 100 cm²/V-s. The patterned polysilicon layer 406′a overlying the patterned protection film 402, however, can get smaller and uniform grain size because the patterned protection film 402 reflects a portion of laser. The patterned polysilicon layer 406′a has a mobility of about 100 cm²/V-s.

As shown in FIG. 4f, a gate dielectric layer 410 is formed to cover the buffer layer 402 and patterned polysilicon layers i.e. the first active layer, second active layer.

As shown in FIG. 4g, subsequent processes proceeds in sequence, forming gate electrodes 412 and 414, interlayer dielectric 416, conductive line 418, cap layer 420 and transparent electrode (pixel electrode) 424. The subsequent processes are well known, thus are omitted here. As a result, an organic electroluminescent device 4000 with switching and driving TFTs is obtained. The switching TFT includes a gate electrode 412, a gate dielectric layer 410 and a first active layer; the driving TFT includes a gate electrode 414, a gate dielectric layer 410 and a second active layer. The first active layer includes a channel region 406′d, lightly doped drains 406′b, source/drain electrodes 406′c; the second active layer includes a channel region 406c and source/drain electrodes 406d.

### Fourth Embodiment

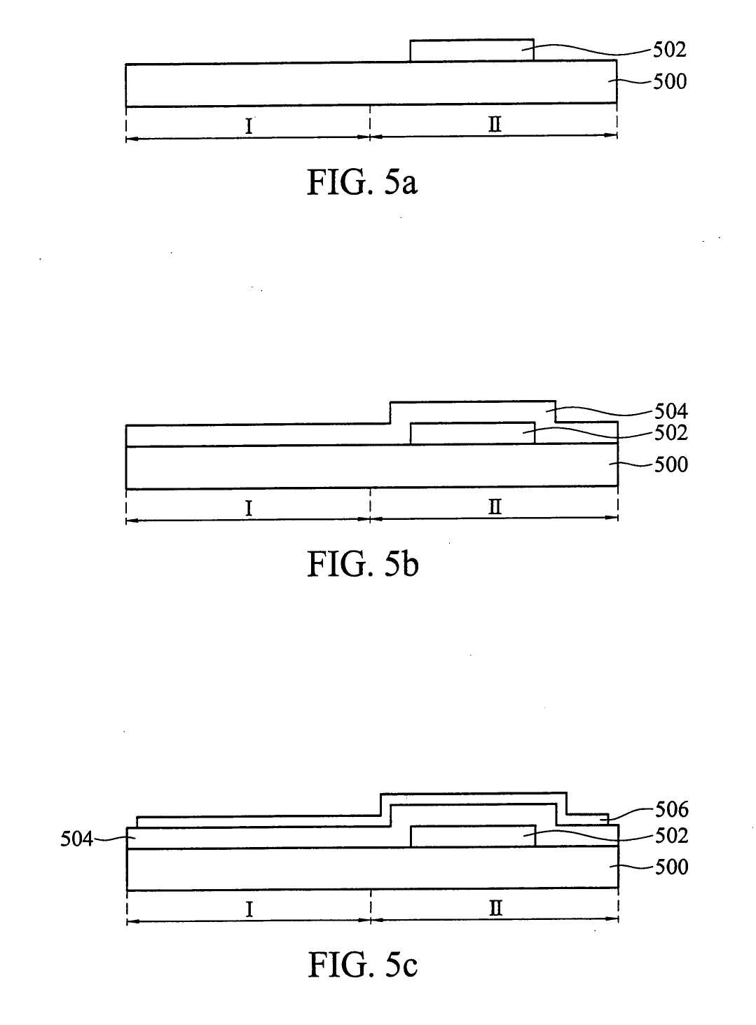

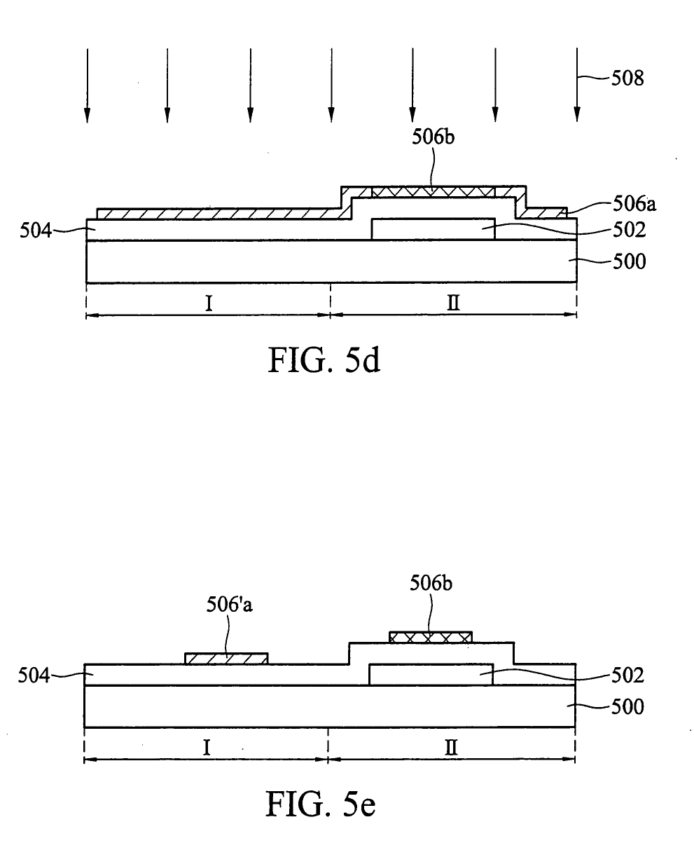

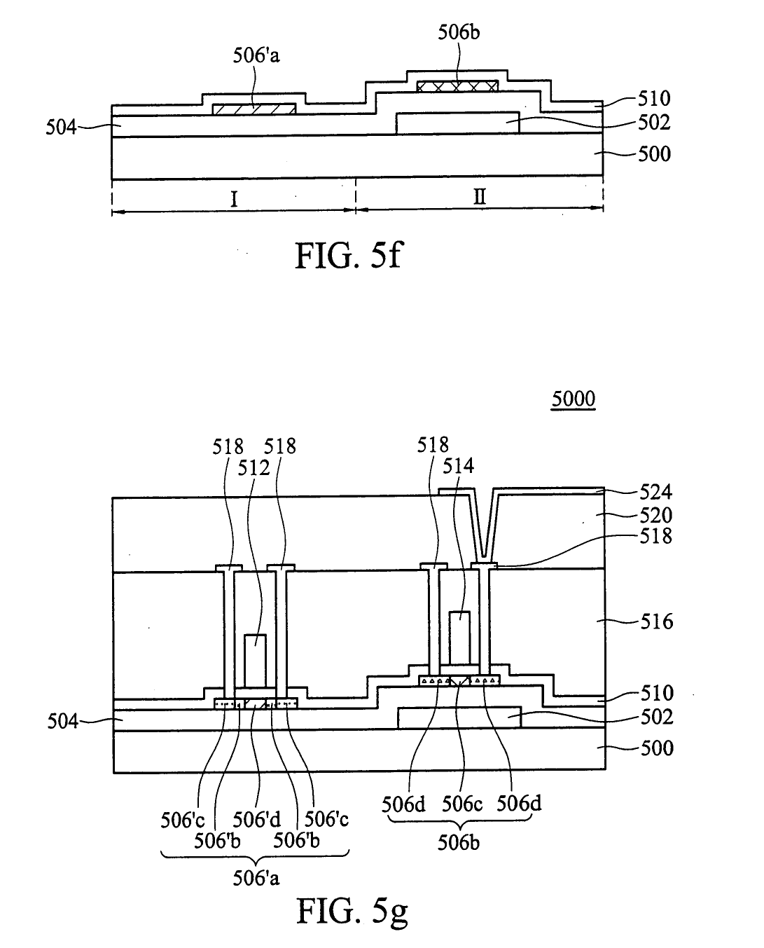

FIGS. 5a˜5g are cross sections showing an embodiment of a method for fabricating an organic electroluminescent device.

As shown in FIG. 5a, a patterned protection film 502 is formed overlying a substrate 500 divided into a switching TFT region I and a driving TFT region II. Furthermore, the patterned protection film 502 in the driving TFT region II and can be any metal materials.

As shown in FIG. 5b, a buffer layer 504 is formed overlying the patterned protection film 502 and the substrate 500. As shown in FIG. 5c, an amorphous silicon layer 506 is formed overlying the buffer layer 504.

As shown in FIG. 5d, the amorphous silicon layer 506 proceeds an excimer laser annealing (ELA) process 508 and transforms to polysilicon layers 506a and 506b.

As shown in FIG. 5e, patterned polysilicon layers 506′a and 506b are formed after a patterning process of the polysilicon layers 506a and 506b. The polysilicon layers 506′a in the switching TFT region I serves a first active layer of the switching TFT formed later and the polysilicon layer 506b in the driving TFT region II serves a second active layer of the driving TFT formed later. The polysilicon layers 506′a and 506b, however, have different grain size because the patterned protection film 502 possess a higher thermal conductivity that can dissipate the heat easier than other portion. That is, the patterned polysilicon layer 506′a possesses greater grain size due to its direct exposure to the excimer laser, and has a mobility of about 100 cm²/V-s. In contrast, the patterned polysilicon layer 506′a overlying the patterned protection film 502 can get smaller and uniform grain size. The patterned polysilicon layer 506′a has a mobility of about 100 cm²/V-s.

As shown in FIG. 5f, a gate dielectric layer 510 is formed to cover the buffer layer 502 and patterned polysilicon layers i.e. the first active layer, second active layer.

As shown in FIG. 5g, subsequent processes proceeds in sequence, forming gate electrodes 512 and 514, interlayer dielectric 516, conductive line 518, cap layer 520 and transparent electrode (pixel electrode) 524. The subsequent processes are well known, thus are omitted here. As a result, an organic electroluminescent device 5000 with switching and driving TFTs is obtained. The switching TFT includes a gate electrode 512, a gate dielectric layer 510 and a first active layer; the driving TFT includes a gate electrode 514, a gate dielectric layer 510 and a second active layer. The first active layer includes a channel region 506′d, lightly doped drains 506′b, source/drain electrodes 506′c; the second active layer includes a channel region 506c and source/drain electrodes 506d.

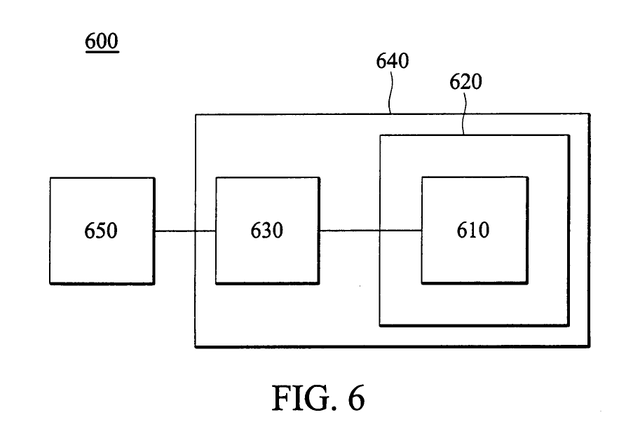

FIG. 6 schematically shows another embodiment of a system for displaying images which, in this case, is implemented as a display panel 620, a flat panel device 640 or an electronic device 600. The described active matrix organic electroluminescent device can be incorporated into a display panel that can be an organic light emitting diode (OLED) panel. As shown in FIG. 6, the display panel 620 comprises an active matrix organic electroluminescent device 610, such as the active matrix organic electroluminescent devices 2000, 3000 and 4000 respectively shown in FIGS. 2f, 3f and 4g. In other embodiments, a flat panel device 640 can be composed of the display panel 620 and a controller 630. In other embodiments, the display panel 620 can also form a portion of a variety of electronic devices (in this case, electronic device 600). Generally, the electronic device 600 can comprise the flat panel device 640 including the display panel 620, the controller 630 and an input unit 650. Further, the input unit 650 is operatively coupled to the flat panel device 640 and provides input signals (e.g., an image signal) to the display panel 620 to generate images. The electronic device 600 can be a mobile phone, digital camera, PDA (personal digital assistant), notebook computer, desktop computer, television, car display, or portable DVD player, for example.

As described above, in the embodiments of the invention, an excimer laser annealing (ELA) process is utilized to form additional passivation film or metal film overlying or/and underlying the buffer layer. In other embodiments, additional protection film or metal film is formed on the gate insulating layer. In this way, the switching TFT and driving TFT possess different grain size. As a result, a more uniform driving current can flow in an active matrix organic electroluminescent device including the TFTs with different grain size, thus defects like mura are avoided.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for fabricating organic electroluminescent devices, comprising:
providing a substrate comprising a pixel area including a plurality of pixels, wherein each pixel is divided into first and second regions;
forming an amorphous silicon layer on the substrate;
forming a protection film on the amorphous silicon layer within the second region;
performing an excimer laser annealing process on the amorphous silicon layer for converting it to a polysilicon layer; and
patterning the polysilicon layer, thus a first patterned polysilicon layer in the first region and a second patterned polysilicon layer in the second region are formed, wherein the grain size of the first patterned polysilicon layer is large than that of the second patterned polysilicon layer.

2. The method as claimed in claim 1, wherein the protection film comprises Si-based materials.

3. The method as claimed in claim 1, wherein the protection film is employed in the excimer laser annealing process for reflecting a portion of the excimer laser.

4. The method as claimed in claim 1, further comprises:
forming a gate insulating layer overlying the patterned polysilicon layer post the step of patterning the polysilicon layer.

5. The method as claimed in claim 1, wherein the first patterned polysilicon layer in the first region is a first active layer and forms a switching TFT, and the second patterned polysilicon layer in the second region is a second active layer and forms a driving TFT.

6. The method as claimed in claim 1, wherein the protection film is removed after the excimer laser annealing process.

7. The method as claimed in claim 1, wherein first and second patterned amorphous silicon layers are formed in the first and second regions, respectively, by patterning the amorphous silicon layer immediately after the formation thereof on the substrate.

8. The method as claimed in claim 7, wherein the protection film comprises Si-based materials.

9. The method as claimed in claim 7, wherein the protection film is employed in the excimer laser annealing process for reflecting a portion of the excimer laser.

10. The method as claimed in claim 7, further comprises:
forming a gate insulating layer overlying the polysilicon layer uncovered by the protection film, substrate and the protection film post t the excimer laser annealing process.

11. The method as claimed in claim 7, wherein the first patterned polysilicon layer in the first region is a first active layer and forms a switching TFT, and the second patterned polysilicon layer in the second region is a second active layer and forms a driving TFT.

12. A method for fabricating an organic electroluminescent device, comprising:
providing a substrate comprising a pixel area including a plurality of pixels, wherein each pixel is divided into first and second regions;
forming a patterned protection film overlying the second region;
forming a amorphous silicon layer overlying the substrate and patterned protection film;
performing an excimer laser annealing process on the amorphous silicon layer for converting it to a polysilicon layer; and
patterning the polysilicon layer, thus a first patterned polysilicon layer in the first region and a second patterned polysilicon layer in the second region are formed, wherein the grain size of the first patterned polysilicon layer is large than that of the second patterned polysilicon layer.

13. The method as claimed in claim 12, wherein the patterned protection film comprises metal materials.

14. The method as claimed in claim 12, wherein the patterned protection film possess a higher thermal conductivity in the excimer laser annealing process.

15. The method as claimed in claim 12, further comprises:
forming a gate insulating layer overlying the patterned polysilicon layer and the substrate post the step of patterning the polysilicon layer.

16. The method as claimed in claim 12, wherein the first patterned polysilicon layer in the first region is a first active layer and forms a switching TFT, and the second patterned polysilicon layer in the second region is a second active layer and forms a driving TFT.

17. A system for displaying images, comprising:
an organic electroluminescent device, comprising:
a substrate with a pixel area thereon; wherein the pixel area comprises a plurality of pixels, each pixel comprising:
a switching region and a driving region;
a switching TFT in the switching region; and
a driving TFT in the driving region, at least comprising a gate electrode, a polysilicon layer underlying the gate electrode and a patterned protection film underlying the polysilicon layer, wherein the patterned protection film that is a metal layer is between the polysilicon layer and the substrate.

18. The system as claimed in claim 17, further comprising a display panel, wherein the organic electroluminescent device forms a portion of the display panel.

19. The system as claimed in claim 18, further comprising an electronic device, wherein the electronic device comprises:
the display panel; and
an input unit coupled to the display panel and operative to provide input to the display panel such that the display panel displays images.

20. The system as claimed in claim 19, wherein the electronic device is a mobile phone, digital camera, PDA (personal digital assistant), notebook computer, desktop computer, television, car display, or portable DVD player.
